(19) United States
(12) Patent Application Publication
(10) Pub. No.: US 2022/0155344 A1
(43) Pub. Date: May 19, 2022

(54) MANUFACTURING METHOD FOR MANUFACTURING CONTACT PROBES FOR PROBE HEADS OF ELECTRONIC DEVICES AND CORRESPONDING CONTACT PROBE

(71) Applicant: Technoprobe, S.p.A., Cernusco Lombardone (LC) (IT)

(72) Inventor: Roberto CRIPPA, Cernusco Lombardone LC (IT)

(21) Appl. No.: 17/591,349

(22) Filed: Feb. 2, 2022

Related U.S. Application Data
(63) Continuation-in-part of application No. PCT/EP2020/071909, filed on Aug. 4, 2020.

(30) Foreign Application Priority Data
Aug. 7, 2019 (IT) 102019000014214

(51) Int. Cl. G01R 1/067; B33Y 10/00; B33Y 80/00; B22F 10/22; B28B 1/00

(52) U.S. Cl. CPC G01R 1/067; B33Y 10/00; B28B 1/001; B22F 10/22; B33Y 80/00

(57) ABSTRACT

A manufacturing method for manufacturing at least one contact probe for a probe head of a test equipment of electronic devices, comprising a step of submicrometric 3D printing of the contact probe with at least one printing material selected from a conductor material or a semiconductor material is disclosed.

### RELATED APPLICATIONS

The present application is a Continuation-in-Part (CIP) application of Int. Pat. App. No. PCT/EP2020/071909, filed Aug. 4, 2020 and entitled “MANUFACTURING METHOD FOR MANUFACTURING CONTACT PROBES FOR PROBE HEADS OF ELECTRONIC DEVICES AND CORRESPONDING CONTACT PROBE”, which claims priority to Italian Pat. App. No. 102019000014214, filed Aug. 7, 2019, the entire disclosures of which applications are hereby incorporated herein by reference.

### TECHNICAL FIELD

The present disclosure refers, in a more general aspect thereof, to a manufacturing method for manufacturing contact probes for a probe head of electronic devices, as well as to the corresponding contact probe, and the following description is made with reference to this field of application with the sole purpose of simplifying the exposure thereof.

### DESCRIPTION OF THE RELATED ART

As is well known, a probe head is essentially a device adapted to electrically connect a plurality of contact pads of a microstructure, in particular an electronic device integrated on a wafer, with corresponding channels of a test equipment which verifies the functionality thereof, in particular the electrical one, or generically the test.

The test carried out on integrated devices is namely used to detect and isolate defective devices already in the production phase. Normally, the probe heads are then used for the electrical test of the devices integrated on a wafer before cutting and mounting them inside a chip containment package.

A probe head normally comprises a large number of contact elements or contact probes formed by special alloys with good electrical and mechanical properties and equipped with at least a contact portion for a corresponding plurality of contact pads of a device to be tested.

A kind of probe head commonly indicated as “vertical probe head” essentially comprises a plurality of contact probes held by at least a pair of substantially plate-like and parallel plates or guides. Said guides are equipped with suitable holes and placed at a certain distance from each other so as to leave a free zone or air zone for movement and possible deformation of the contact probes. The pair of guides comprises in particular an upper guide and a lower guide, both of which are provided with respective guide holes in which the contact probes, normally formed by special alloys with good electrical and mechanical properties, slide axially.

The good connection between the contact probes and the respective contact pads of the device to be tested is ensured by the pressure of the probe head on the device itself, the contact probes, movable within the guide holes made in the upper and lower guides, undergoing during said pressing contact a bending inside the air zone between the two guides and a sliding inside said guide holes.

Furthermore, the bending of the contact probes in the air zone can be aided through a suitable configuration of the probes themselves or of their guides, as schematically illustrated in FIG. 1, where for simplicity's sake of illustration only one contact probe of the plurality of probes normally included in a probe head has been represented, the illustrated probe head being of the so-called shifted plate kind.

In particular, FIG. 1 schematically shows a probe head 9 comprising at least one upper plate or guide (upper die) 2 and one lower plate or guide (lower die) 3, having respective upper 2A and lower 3A guide holes within which at least one contact probe 1 having a probe body 1C extended essentially in a longitudinal development direction according to the axis H-H indicated in the figure slide. A plurality of contact probes 1 is usually located inside the probe head 9 with said longitudinal development direction arranged orthogonally to the device to be tested and to the guides, that is substantially vertically along the axis z using the local reference of the figure.

The contact probe 1 has at least one contact end or tip 1A. The term end or tip indicates herein and in the following an ending portion, not necessarily a pointed one. In particular, the contact tip 1A abuts onto a contact pad 4A of a device to be tested 4, realizing the mechanical and electrical contact between said device and a test equipment (not shown) of which the probe head 9 forms a terminal element.

In some cases, the contact probes are constrained to the probe head at the upper guide in a fixed manner: these are called probe heads with blocked probes.

Alternatively, probe heads are used with probes not fastened in a fixed manner, but kept interfaced to a board by means of an intermediate board: these are called probe heads with non-blocked probes. The intermediate board is a space transformation board, usually called a “space transformer” which, in addition to the contact with the probes, also allows to spatially redistribute the contact pads provided on it, with respect to the contact pads present on the device to be tested, in particular with a loosening of the distance constraints between the centers of the pads themselves, that is to say with a transformation of the space in terms of distances between the centers of adjacent pads.

In this case, as illustrated in FIG. 1, the contact probe 1 has a further contact tip 1B, in the field indicated as a contact head, towards a plurality of contact pads 5A of such a space transformer 5. The good electrical contact between probes and space transformer 5 is ensured in a similar way to the contact with the device to be tested 4 by the pressure of the contact heads 1B of the contact probes 1 onto the contact pads 5A of the space transformer 5.

As already explained, the upper guide 2 and the lower guide 3 are suitably spaced by an air zone 6 which allows the deformation of the contact probes 1 during the operation of the probe head 9 and ensures the connection of the contact tip and contact head, 1A and 1B, of the contact probes 1 with the contact pads, 4A and 5A, of the device to be tested 4 and of the space transformer 5, respectively. Obviously, the upper guide holes 2A and lower guide holes 3A should be sized so as to allow a sliding of the contact probe 1 inside them during the testing operations carried out by means of the probe head 9.

It should be noted that the sizing of said upper guide holes 2A and lower guide holes 3A also depends on the dimensional tolerances of the contact probes 1 which should be housed in them, which tolerances result in increased dimensions and therefore a greater overall volume of said upper guide holes 2A and lower guide holes 3A, a lower number of the same being able to be placed on the respective guides, as schematically illustrated in FIG. 2, with reference to the upper guide 2 and to the detail thereof shown enlarged in FIG. 2A, where respective clearances Gx and Gy provided at the two development directions of said guide holes 2A, in particular according to the axes x and y indicated in the figure, are shown. Similar clearances are provided for the lower guide holes 3A of the lower guide 3.

More specifically, said clearances are established so as to ensure the correct insertion, holding and sliding of the contact probes 1 in the upper guide holes 2A and lower guide holes 3A in the upper guide 2 and lower guide 3, respectively.

The dimensional tolerances of the contact probes also influence other factors, such as the sizing, for example, of the contact heads 1B so as to ensure that they settle in abutment on the upper guide 2 and allow the correct holding of the contact probes 1 inside the probe head 9 during the normal operation thereof, even in the absence of the wafer of devices to be tested 4 onto which the probe head 9 should abut.

It is also well known that the dimensional tolerances of a contact probe 1 essentially depend on the manufacturing method of the same.

Fundamentally, two manufacturing methods for manufacturing contact probes for a probe head of electronic devices are currently used in the sector.

The first method is based on the photolithographic technique for making probes starting from suitably shaped substrates thanks to the use of subsequent masking and material removal steps, capable of making contact probes with limited dimensional accuracy.

The manufacturing method using a photolithographic technique allows easily to manufacture probes comprising different layers of materials, but seriously limits the overall dimensions of the contact probes and the possibility of creating particularly complex structures, both in terms of geometric shapes and in terms of combinations of usable materials.

The second known method, widely used in the field, is based on the laser cutting technique; in particular, a laser beam is used which is able to “cut out” the contact probes starting from a laminate of a suitable material, possibly also multilayer.

Thanks to the laser method it is possible to create structures with more complex shapes than with the photolithographic technique. It is usually necessary to add further deposition techniques to said laser technique, for example to obtain covering films of the entire contact probes or parts thereof.

None of the known methods, however, allows to obtain optimal dimensional accuracies nor the perfect reproducibility of the same on a same batch of manufactured probes, which entails having to take into consideration a statistically calculated maximum tolerance for each batch.

Furthermore, none of the known methods allows to make probes which comprise alternations of materials in more or less complex shapes.

Also known from US Patent Publication No. US 2017/118846 A1 to Yamada et al. (SAMSUNG ELECTRONICS CO LTD) is a method for manufacturing a test socket including a base material and a first conductive portion included in the base material as well as a second conductive portion including conductive ink being formed based on printing conductive ink on the first conductive portion. Moreover, US Patent Publication No. US 2016/218287 to McAlpine (THE TRUSTEES OF PRINCETON UNIVERSITY) discloses a process whereby diverse classes of materials can be 3D printed and fully integrated into device components with active properties.

### BRIEF SUMMARY

The manufacturing method for manufacturing contact probes for probe heads of integrated devices is able to make probes having geometric shapes of any complexity using any material combinations while ensuring that the obtained probes have a high accuracy, thereby overcoming the limitations and drawbacks that still afflict the methods realized according to the prior art.

According to an aspect of the disclosure, the contact probes are manufactured by 3D printing of suitable printing materials, in particular at least one conductor or semiconductor material, using nozzles for outputting the printing material with submicrometric dimensions.

The manufacturing method for manufacturing at least one contact probe for a probe head of a test equipment of electronic devices comprises a step of submicrometric 3D printing of the probe contact with at least one printing material selected from a conductor material or a semiconductor material, the step of 3D printing can comprising a step of outputting the submicron-sized printing material and a step of depositing the printing material according to a preset geometric 3D shape of the contact probe so obtained, which has dimensions defined with submicrometric accuracy.

According to an aspect of the disclosure, the step of outputting the printing material can comprise a step of forming a wire of said printing material with a diameter in the range of 0.1-0.9 μm, preferably in the range of 0.2-0.4 μm.

According to another aspect of the disclosure, the manufacturing method can comprise a preliminary step of heating the printing material.

In particular, the preliminary heating step can comprise heating the printing material up to a softening point thereof, preferably up to a melting point thereof.

According to another aspect of the disclosure, the step of 3D printing can be carried out by a plurality of different printing materials.

In this case, the step of 3D printing can comprise a plurality of steps of outputting and depositing the plurality of different printing materials according to the preset geometric 3D shape of the contact probe.

Furthermore, the steps of outputting and depositing can be simultaneously or sequentially carried out.

According to another aspect of the disclosure, the 3D printing step can use a conductor material such as a metal selected from copper, silver, gold or alloys thereof, such as copper-niobium or copper-silver alloys or nickel or an alloy thereof, such as nickel-manganese, nickel-cobalt or nickel-phosphorus alloys or tungsten or an alloy thereof, such as nickel-tungsten, or a multilayer containing tungsten, or palladium or an alloy thereof, such as nickel-palladium, palladium-cobalt or palladium-tungsten, or platinum or rhodium or an alloy thereof, preferably tungsten.

According to another aspect of the disclosure, the step of 3D printing uses a semiconductor material, such as silicon or silicon carbide, possibly doped.

Furthermore, according to another aspect of the disclosure, the plurality of different printing materials can comprise one or more conductor materials, such as metals selected from copper, silver, gold or alloys thereof, such as copper-niobium or copper-silver alloys or nickel or an alloy thereof, such as nickel-manganese, nickel-cobalt or nickel-phosphorus alloys or tungsten or an alloy thereof, such as nickel-tungsten, or a multilayer containing tungsten, or palladium or an alloy thereof, such as nickel-palladium, palladium-cobalt or palladium-tungsten, or platinum or rhodium or an alloy thereof, preferably tungsten or one or more semiconductor materials, such as silicon or silicon carbide, possibly doped, or one or more insulating materials, such as parylene®, in any combination.

The disclosure also refers to a contact probe for a probe head of a test equipment of electronic devices, characterized in that it is provided by a step of submicrometric 3D printing with at least one printing material selected from a conductor material or a semiconductor material.

According to another aspect of the disclosure, the contact probe can comprise a plurality of different materials including one or more conductor materials such as metals selected from copper, silver, gold or alloys thereof, such as copper-niobium or copper-silver alloys or nickel or an alloy thereof, such as nickel-manganese, nickel-cobalt or nickel-phosphorus alloys or tungsten or an alloy thereof, such as nickel-tungsten, or a multilayer containing tungsten, or palladium or an alloy thereof, such as nickel-palladium, palladium-cobalt or palladium-tungsten, or platinum or rhodium or an alloy thereof, preferably tungsten or one or more semiconductor materials such as silicon or silicon carbide, possibly doped, or one or more insulating materials, such as parylene®, in any combination.

In particular, these materials can be combined in an interpenetrated or interlaced shape, possibly jointed with empty portions or air zones.

The characteristics and the advantages of the manufacturing method anf of the contact probe head according to the disclosure will become clear from the description, made below, of an example of its embodiment given by way of non-limiting example with reference to the attached drawings.

### BRIEF DESCRIPTION OF THE SEVERAL VIEWS OF THE DRAWINGS

FIG. 1 schematically shows a front view of a probe head made according to the prior art;

FIGS. 2 and 2A show respectively a plan view of a guide included in the probe head of FIG. 1 and an enlarged detail thereof;

FIG. 3 schematically shows a front view of a 3D printing equipment capable of implementing the manufacturing method according to the present disclosure; and

FIGS. 4A-4E, 5A-5D, 6A-6D and 7A-7B schematically show alternative embodiments of a contact probe made according to the present disclosure.

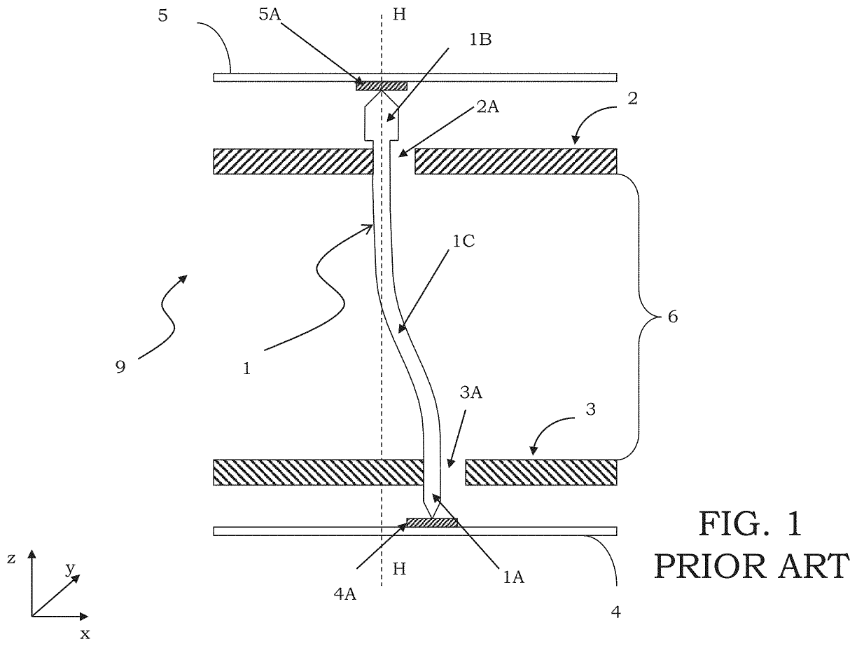

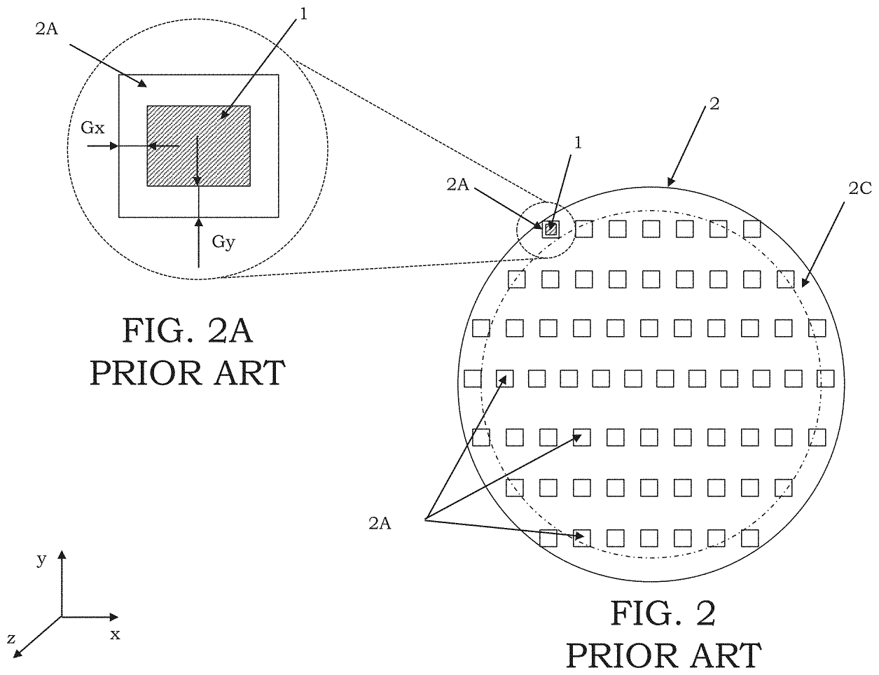

### DETAILED DESCRIPTION

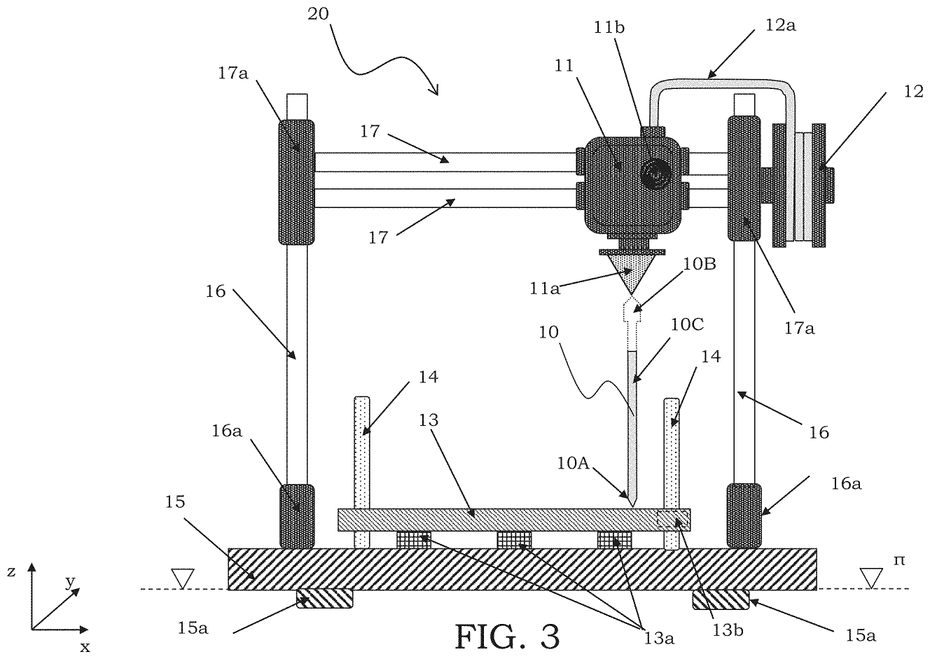

With reference to these figures, and in particular to FIG. 3, a manufacturing method for manufacturing a contact probe for a probe head implemented by means of a 3D printing equipment is described, said 3D printing equipment being indicated as a whole with 20 and the corresponding contact probe thus obtained with 10.

It should be noted that the figures represent schematic views and are not drawn to scale, but are instead designed in such a way as to emphasize the important features of the embodiments.

Furthermore, the process steps described below do not form a complete process flow for manufacturing the contact probes. The present disclosure can be put into practice together with the already known 3D printing techniques, and only those steps of the commonly used process which are necessary for the understanding of the present disclosure are included.

Finally, it should be noted that the measures illustrated in relation to vertical or buckling beam probes can also be shifted to other types of probes, such as cantilever probes, micro-probes and so on, as well as the measures illustrated in relation to cantilever or micro-probes can also be applied to vertical probes.

A manufacturing method for manufacturing at least one contact probe for a probe head of a test equipment of electronic devices comprising a submicrometric 3D printing step of said contact probe 10 with at least one conductor or semiconductor material suitable for the realization of the same is disclosed.

Said conductor material can be a metal such as copper, silver, gold or alloys thereof, such as copper-niobium or copper-silver alloys or nickel or an alloy thereof, such as nickel-manganese, nickel-cobalt or nickel-phosphorus alloys or tungsten or an alloy thereof, such as nickel-tungsten, or a multilayer containing tungsten, or palladium or an alloy thereof, such as nickel-palladium, palladium-cobalt or palladium-tungsten, or platinum or rhodium or an alloy thereof, preferably tungsten. Alternatively, a semiconductor material such as silicon or silicon carbide can be used, which can also be suitably doped to increase the conductive properties thereof.

Suitably, the step of 3D printing comprises a step of outputting the submicron-sized printing material and a step of depositing the printing material according to a preset geometric shape.

More specifically, the step of outputting the printing material comprises a step of forming a wire of said printing material with a diameter in the range of 0.1-0.9 μm, preferably in the range of 0.2-0.4 μm. These dimensions correspond to the limits of the current 3D printing technology, in particular for metallic materials, and can obviously change with the evolution of this technology.

Furthermore, the step of 3D printing can comprise a preliminary step of heating the printing material, in particular up to a softening point of the same, preferably up to a melting point thereof.

In a preferred embodiment, the step of 3D printing is carried out by a plurality of different printing materials.

In this case, said step of 3D printing comprises a plurality of steps of outputting and depositing the different printing materials.

In particular, said printing materials can be conductor or semiconductor materials, selected from those listed above, but they can also be insulating materials, in particular in the shape of coating layers of the contact probe 10, for example parylene®. Insulating materials can also be used to make portions of the contact probe 10 which do not have to carry current, as will be better clarified below.

Suitably, the steps of outputting and depositing can be simultaneously and sequentially carried out.

As schematically illustrated in FIG. 3, the contact probe 10 is printed by means of the 3D printing equipment 20, in particular comprising at least one 3D printing head 11 capable of outputting a submicron-sized printing material. As seen in relation to the prior art, the contact probe 10 comprises at least a first end portion, indicated as a contact tip 10A, a second end portion, indicated as a contact head 10B and a rod-like body 10C which extends between them.

The 3D printing head 11 thus comprises a printing nozzle 11a with a printing material output opening having a submicrometric-sized diameter, in particular in the range of 0.1-0.9 μm, preferably in the range of 0.2-0.4 μm, i.e. corresponding to those of the wire of the printing material.

The printing nozzle 11a is connected to a tank 11b of at least one conductor or semiconductor material suitable for the realization of the contact probe 10, in turn connected to a feeder 12 of said material, by means of suitable means of connection and transport 12a of said material, in the shape, for example, of a small tube. In particular, the 3D printing head 11 can output the printing material for printing the probe in the shape of a wire having a submicron-sized diameter.

The 3D printing equipment 20 can also comprise at least one heater of said printing material, possibly associated with the tank 12.

Said conductor material can be a metal such as copper, silver, gold or alloys thereof, such as copper-niobium or copper-silver alloys or nickel or an alloy thereof, such as nickel-manganese, nickel-cobalt or nickel-phosphorus alloys or tungsten or an alloy thereof, such as nickel-tungsten, or a multilayer containing tungsten, or palladium or an alloy thereof, such as nickel-palladium, palladium-cobalt or palladium-tungsten, or platinum or rhodium or an alloy thereof, preferably tungsten. Alternatively, a semiconductor material such as silicon or silicon carbide can be used, which can also be suitably doped to increase the conductive properties thereof.

As will be better clarified below, the contact probe 10 can also be made by means of a combination of materials and also comprise insulating materials, in particular in the shape of coating layers, for example parylene®, in combination with each other and with conductor or semiconductor materials.

The 3D printing equipment 20 further comprises at least a movable platform 13, equipped with respective resting feet 13a and moved thanks to motor elements 13b, in particular along axes 14 orthogonal to the movable platform 13 itself, which is in the shape of a plate-like support and is positioned on a fixed base 15 of the 3D printing equipment 20, which in turn is provided with resting feet 15a. The fixed base 15 is also in the shape of a plate and develops according to a plane π.

The 3D printing equipment 20 also comprises first support uprights 16 positioned orthogonally to the fixed base 15 and associated therewith by means of first fixing elements 16a. Further second support uprights 17 are provided, orthogonal to the first support uprights 16 and connected thereto by means of second fixing elements 17a.

More specifically, the second support uprights 17 carry the 3D printing head 11 on board and allow the movement thereof in the plane π of the fixed base 15 of the 3D printing equipment 20.

By using the local reference system of the figure, the 3D printing head 11 is therefore movable according to the axes x and y, while the movable platform 13 moves along the axis z. It is obviously possible to consider configurations in which also the movable platform 13 is able to move according to the axes x and y and to move the 3D printing head 11 according to the axis z or any other combination of movements.

In any case, the combination of the movements of the 3D printing head 11 and of the movable platform 13 allows the printing nozzle 11a to be moved according to the three directions x, y and z, so that the contact probe 10 can be realized according to a preset geometric shape.

It is immediately evident how the 3D printing equipment 20 allows printing a contact probe 10 also having geometrically complex shapes, in particular shapes not obtainable with the desired accuracy by means of traditional photolithographic and laser techniques.

In particular, any contact probe 10 obtained by the above described manufacturing method comprising submicrometric 3D printing, thanks to the 3D printing equipment 20 described above, will have dimensions with dimensional accuracies lower than one micron, regardless of the complexity of the final geometric shape thereof.

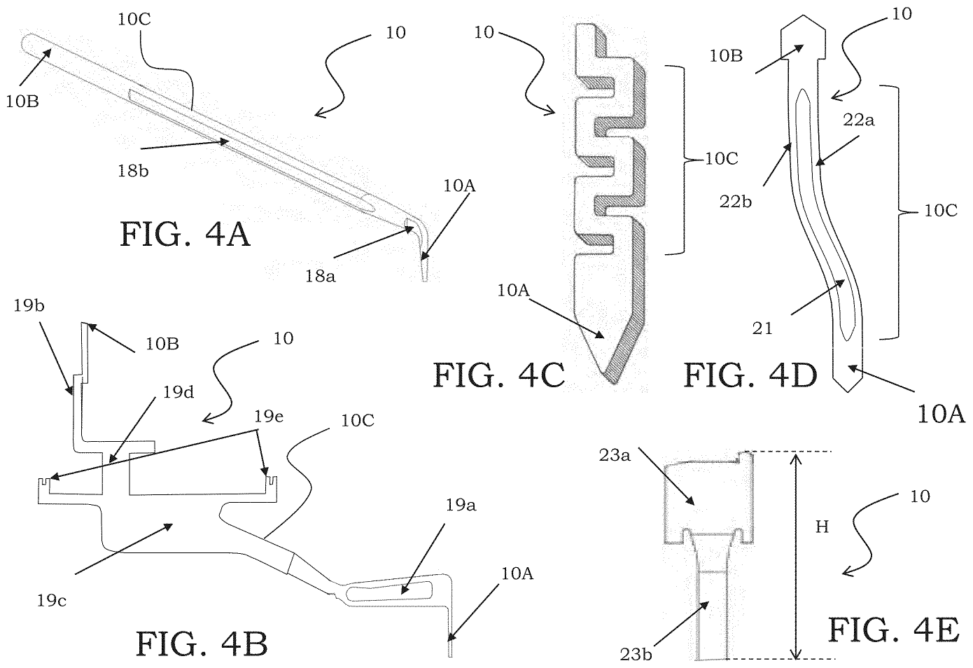

It is thus possible to obtain a contact probe 10 having suitable notches capable of locally reducing the dimensions, as schematically illustrated in FIG. 4A, in the case of a cantilever contact probe equipped with a first notch 18a made at a portion end, such as the contact tip 10A and a second notch 18b made at the body 10C.

Similarly, by 3D printing it is possible to realize a contact probe with an overall very complicated geometric shape such as the one shown in FIG. 4B. More specifically, the contact probe 10 comprises a pantograph structure 19a realized at the contact tip 10A, a dampening structure 19b realized at the contact head 10B and a body having an enlarged shape 19c equipped with a T-shaped top portion 19d and respective coupling feet 19d.

Thanks to 3D printing it is also possible to realize complex shapes with full and empty portions, even just a portion of the contact probe 10, for example the body 10C as illustrated in FIG. 4C, where the body 10C is made in the shape of a coil.

Similarly, as illustrated in FIG. 4D, it is possible to realize the body 10C as a plurality of lamellae 22a, 22b separated by a suitable separation zone 21, which can be air or other material.

Finally, as schematically illustrated in FIG. 4E, it is also possible to print probes of reduced dimensions, such as micro-probes, having portions contact 23a and portions support 23b of any shape and height H lower than 200 μm.

Advantageously, the 3D printing of the manufacturing method according to an embodiment of the present disclosure can also provide for the printing of different printing materials for different portions of the contact probe 10. In this case it is possible to provide for the connection of the 3D printing head 11 of the 3D printing equipment 20 to a plurality of feeders 12 of the different printing materials, in a fixed or interchangeable manner, so as to carry out the steps of outputting and depositing the different print materials simultaneously or sequentially.

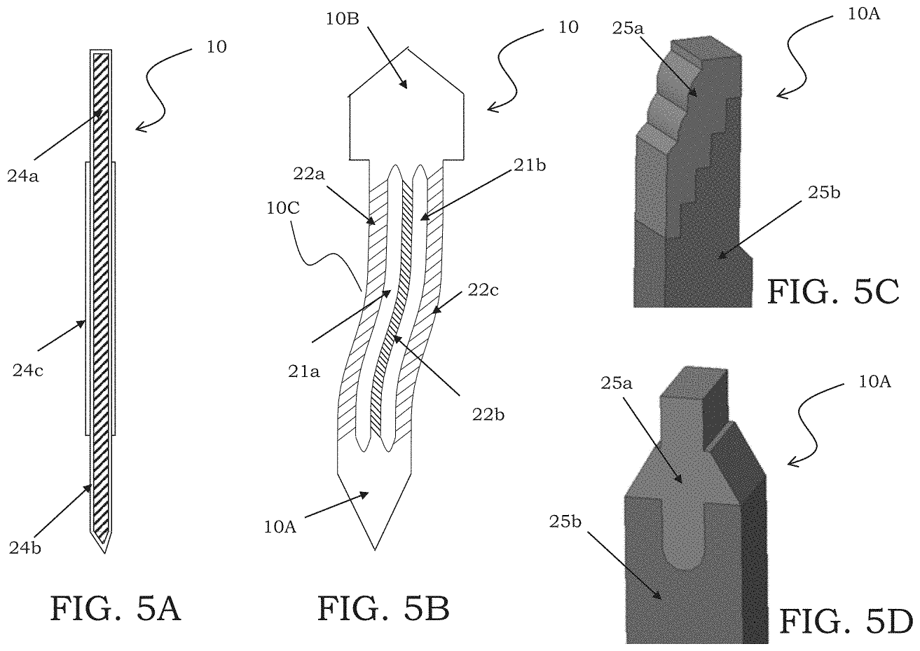

In this way it is possible to obtain a contact probe 10 of the multilayer type, as schematically illustrated in FIG. 5A, having a rod-like core 24a and several coating layers, which cover the core 24a totally like the layer 24b or only partially like the layer 24c.

It is similarly possible to realize a contact probe 10 equipped with a plurality of lamellae 22a, 22b and 22c and with separation zones 21a, 21b, at least one or even all the lamellae and/or the separation zones being made of different materials, as schematically illustrated in FIG. 5B.

Furthermore, as shown in FIGS. 5C and 5D, it is possible to realize also only a portion of the contact probe 10, such as the contact tip 10A, as well as at least a pair of zones 23a and 23b made of at least two different materials, said zones 23a and 23b being able to have complex geometric shapes and in particular corresponding and conjugated at their interface portions, to guarantee a better structural stability of the contact tip 10A thus obtained.

Advantageously according to an embodiment of the disclosure, the 3D printing method can realize complex shapes even only in a superficial portion of the contact probe 10.

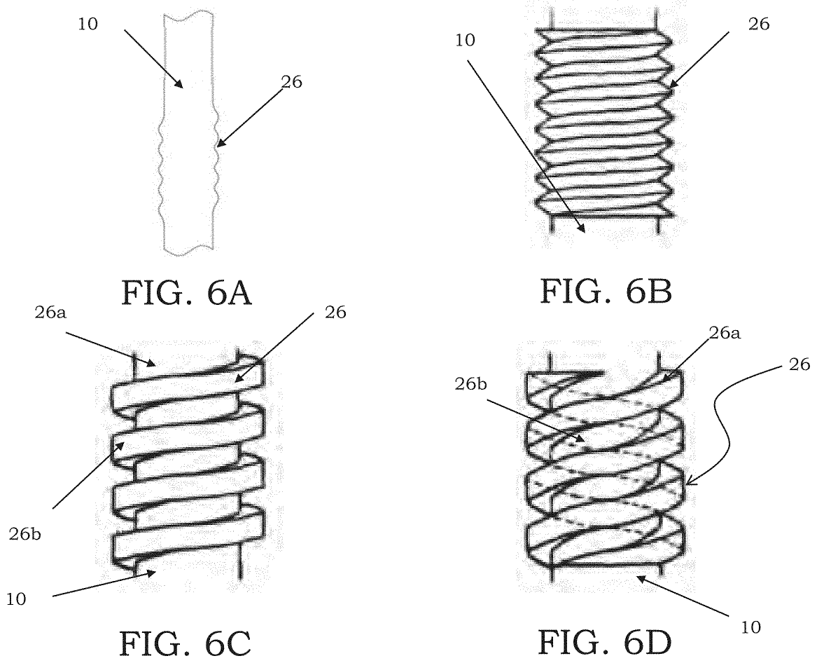

In this way it is possible to obtain a contact probe 10 having a surface portion 26, slightly corrugated as schematically illustrated in FIG. 6A or more markedly corrugated, in the form of a real surface sleeve, as schematically illustrated in FIG. 6B.

Suitably, said corrugated surface portion 26 can also be made by means of separate interlaced portions, possibly made by different materials, as schematically illustrated in FIGS. 6C and 6D.

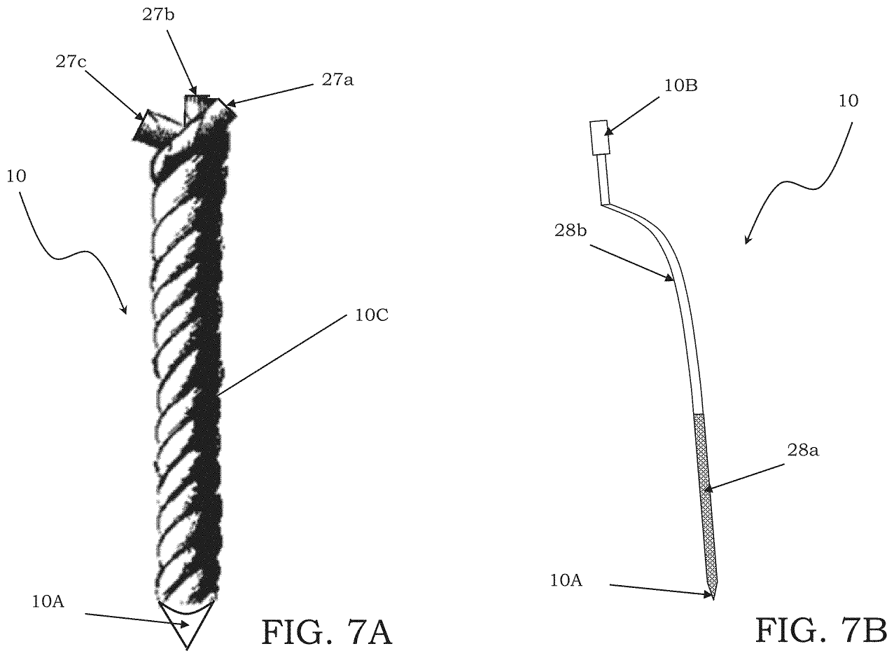

In an even more complex embodiment, the 3D printing of the method according to an embodiment of the present disclosure also allows the contact probe 10 to be manufactured in an entirely interlaced form, in particular by means of three wires 27a, 27b and 27c, possibly made of different printing materials and/or with different diameters, as schematically illustrated in FIG. 7A.

Furthermore, the contact probe 10 can be made so as to comprise distinct portions 28a, 28b made of different materials, as schematically illustrated in FIG. 7B. In this case, the contact probe 10 comprises a first portion 28a made of a first material and comprising the contact tip 10A and a second portion 28b made of a second material and comprising the contact head 10B. Said first and second materials can for example be both conductor materials, having different properties; in particular, the first material making the first portion 28a can be chosen so as to have higher hardness values than those of the second material making the second portion 28b, so as to confer greater hardness to the contact tip 10A of the contact probe 10. Alternatively, it is possible to make the first portion 28a of a conductor material and the second portion 28b of an insulating material, said second portion becoming in fact a dampening portion only for a probe having reduced dimensions with respect to those of the first portion 18a.

It is therefore pointed out that the manufacturing method according to the embodiments of the present disclosure allows to 3D print a contact probe 10 which can comprise a combination of different materials, conductor, semiconductor or even insulated ones, in interpenetrated or interlaced form, possibly jointed with empty portions or air zones.

In conclusion, the manufacturing method according to the embodiments of the present disclosure, thanks to the 3D printing, allows to obtain in a safe and reproducible way probes made by any combination of materials and having submicrometric sizing accuracies.

Advantageously, said method allows to obtain probes with particularly complex shapes and combinations of materials that are difficult to obtain using traditional photolithographic and laser techniques.

More particularly, the contact probe obtained by 3D printing can comprise alternations of materials also in an interpenetrated or interlaced shape, possibly jointed with empty portions, even for particularly small overall dimensions, the dimensions of the definitive geometric shape of said probes being however accurate up to the level lower than a micron.

Obviously, a person skilled in the art can make numerous modifications and variations to the manufacturing method and to the contact probe described above, in order to satisfy contingent and specific needs, all included in the scope of protection of the disclosure as defined by the following claims.

In particular, it is obviously possible to consider geometric shapes other than those illustrated by way of example in the figures.

It is also possible to make probes of different types, such as vertical or buckling beam probes, in particular of the blocked or non-blocked type, with free body, pre-deformed, cantilever, micro-probes, contact tips for heads with membrane or even pogo pins.

Furthermore, it is possible to consider other conductor, semiconductor or insulating materials among those known to those skilled in the art for the realization of contact probes, as well as a multilayer combination of the same, both in planar overlap and in concentric or coaxial manner.

Finally, it is possible to equip the contact probe of the present disclosure with further measures, such as particular conformations for the head portion, such as recesses or enlarged portions, the tip portion, as offsets or elongated portions, as well as for the body, like stoppers projecting from the same.

From the foregoing it will be appreciated that, although specific embodiments of the disclosure have been described herein for purposes of illustration, various modifications may be made without deviating from the spirit and scope of the disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A manufacturing method for manufacturing at least one contact probe for a probe head of a test equipment of electronic devices, comprising:
a step of submicrometric 3D printing of the contact probe as a whole with at least one printing material selected from a conductor material or a semiconductor material, the contact probe so obtained having dimensions defined with submicrometric accuracy.

2. The manufacturing method according to claim 1, wherein the step of 3D printing comprises:
a step of outputting the submicron-sized printing material; and
a step of depositing the printing material according to a preset geometric 3D shape of the contact probe.

3. The manufacturing method according to claim 2, wherein the step of outputting the printing material comprises a step of forming a wire of the printing material with a diameter in the range of 0.1-0.9 μm.

4. The manufacturing method according to claim 2, wherein the step of outputting the printing material comprises a step of forming a wire of the printing material with a diameter in the range of 0.2-0.4 μm.

5. The manufacturing method according to claim 1, further comprising a preliminary step of heating the printing material.

6. The manufacturing method according to claim 5, wherein the preliminary step of heating comprises heating the printing material up to a softening point thereof.

7. The manufacturing method according to claim 5, wherein the preliminary step of heating comprises heating the printing material up to a melting point thereof.

8. The manufacturing method according to claim 1, wherein the step of 3D printing is carried out by a plurality of different printing materials.

9. The manufacturing method according to claim 8, wherein the step of 3D printing comprises a plurality of steps of outputting and depositing the plurality of different printing materials according to a preset geometric 3D shape of the contact probe.

10. The manufacturing method according to claim 9, wherein the steps of outputting and depositing are simultaneously carried out.

11. The manufacturing method according to claim 9, wherein the steps of outputting and depositing are sequentially carried out.

12. The manufacturing method according to claim 1, wherein the step of 3D printing uses a conductor material such as a metal selected from copper, silver, gold or alloys thereof, such as copper-niobium or copper-silver alloys or nickel or an alloy thereof, such as nickel-manganese, nickel-cobalt or nickel-phosphorus alloys or tungsten or an alloy thereof, such as nickel-tungsten, or a multilayer containing tungsten, or palladium or an alloy thereof, such as nickel-palladium, palladium-cobalt or palladium-tungsten, or platinum or rhodium or an alloy thereof.

13. The manufacturing method according to claim 1, wherein the step of 3D printing uses tungsten.

14. The manufacturing method according to claim 1, wherein the step of 3D printing uses a semiconductor material, such as silicon or silicon carbide, or a doped semiconductor material, such as doped silicon or doped silicon carbide.

15. The manufacturing method according to claim 1, wherein the step of 3D printing uses an insulating material in the shape of a coating layer of the contact probe.

16. The manufacturing method according to claim 8, wherein the plurality of different printing materials comprise one or more conductor materials, such as metals selected from copper, silver, gold or alloys thereof, such as copper-niobium or copper-silver alloys or nickel or an alloy thereof, such as nickel-manganese, nickel-cobalt or nickel-phosphorus alloys or tungsten or an alloy thereof, such as nickel-tungsten, or a multilayer containing tungsten, or palladium or an alloy thereof, such as nickel-palladium, palladium-cobalt or palladium-tungsten, or platinum or rhodium or an alloy thereof, or one or more semiconductor materials, such as silicon or possibly doped silicon carbide, or one or more insulating materials, in any combination.

17. A contact probe for a probe head of a test equipment of electronic devices, being provided by a step of submicrometric 3D printing with at least one printing material selected from a conductor material or a semiconductor material, the contact probe having dimensions defined with submicrometric accuracy.

18. The contact probe according to claim 17, further comprising a plurality of different materials including one or more conductor materials such as metals selected from copper, silver, gold or alloys thereof, such as copper-niobium or copper-silver alloys or nickel or an alloy thereof, such as nickel-manganese, nickel-cobalt or nickel-phosphorus alloys or tungsten or an alloy thereof, such as nickel-tungsten, or a multilayer containing tungsten, or palladium or an alloy thereof, such as nickel-palladium, palladium-cobalt or palladium-tungsten, or platinum or rhodium or an alloy thereof or one or more semiconductor materials such as silicon or silicon carbide, possibly doped, or one or more insulating materials, in any combination.

19. The contact probe according to claim 18, wherein the materials are combined in an interpenetrated or interlaced shape.

20. The contact probe according to claim 18, wherein the materials are jointed with empty portions or air zones.
